(19) United States
(12) Patent Application Publication
(10) Pub. No.: US 2025/0286022 A1
(43) Pub. Date: Sep. 11, 2025

(54) ELECTRONIC DEVICE AND METHOD FOR OPERATING ELECTRONIC DEVICE

(71) Applicants: Kabushiki Kaisha Toshiba, Tokyo (JP); Toshiba Electronic Devices & Storage Corporation, Tokyo (JP)

(72) Inventors: Kazuyuki HIGASHI, Yokohama Kanagawa (JP); Tomohiro SAITO, Yokohama Kanagawa (JP); Kazumichi TSUMURA, Shinagawa Tokyo (JP)

(21) Appl. No.: 19/041,863

(22) Filed: Jan. 30, 2025

(30) Foreign Application Priority Data
Mar. 7, 2024 (JP) 2024-035008

(51) Int. Cl. H01L 25/07; H01L 21/66; H01L 23/00; H01L 23/48; H10D 84/80

(52) U.S. Cl. CPC H01L 25/074; H01L 22/12; H01L 23/481; H01L 24/16; H10D 84/811

(57) ABSTRACT

A first chip includes a first substrate. The first substrate includes a first surface and a control circuit. A second chip includes a second substrate and an electrode. The second substrate includes a second surface facing the first surface. A plurality of bonding parts is located between the first surface and the second surface. One of the plurality of bonding parts electrically connects the control circuit and the electrode. The second substrate includes a diode electrically connected with the electrode and the plurality of bonding parts. A direction from the diode toward the electrode is a forward direction of the diode. A direction from the control circuit toward the diode via the one of the plurality of bonding parts is a reverse direction of the diode.

### CROSS-REFERENCE TO RELATED APPLICATION

This application is based upon and claims the benefit of priority from Japanese Patent Application No. 2024-035008, filed on Mar. 7, 2024; the entire contents of which are incorporated herein by reference.

### FIELD

Embodiments described herein relate generally to an electronic device and a method for operating an electronic device.

### BACKGROUND

A known device includes two chips bonded by a metal-to-metal bond.

### BRIEF DESCRIPTION OF THE DRAWINGS

FIGS. 1 and 2 are schematic views showing a configuration of an electronic device of a first embodiment;

FIG. 3 is a schematic cross-sectional view showing a configuration of an electronic device of a second embodiment; and

FIG. 4 is a schematic plan view showing a configuration of a first surface side of a first substrate of the electronic device of the second embodiment.

### DETAILED DESCRIPTION

According to one embodiment, an electronic device includes a first chip including a first substrate, the first substrate including a first surface and a control circuit; a second chip including a second substrate and an electrode, the second substrate including a second surface facing the first surface in a first direction; and a plurality of bonding parts located between the first surface and the second surface, one of the plurality of bonding parts electrically connecting the control circuit and the electrode, the plurality of bonding parts bonding the first chip and the second chip, the second substrate including a diode electrically connected with the electrode and the plurality of bonding parts, a direction from the diode toward the electrode being a forward direction of the diode, a direction from the control circuit toward the diode via the one of the plurality of bonding parts being a reverse direction of the diode.

Exemplary embodiments will now be described with reference to the drawings.

The drawings are schematic or conceptual; and the relationships between the thickness and width of portions, the proportional coefficients of sizes among portions, etc., are not necessarily the same as the actual values thereof. Furthermore, the dimensions and proportional coefficients may be illustrated differently among drawings, even for identical portions.

In the specification of the application and the drawings, components similar to those described in regard to a drawing thereinabove are marked with like reference numerals, and a detailed description is omitted as appropriate.

### First Embodiment

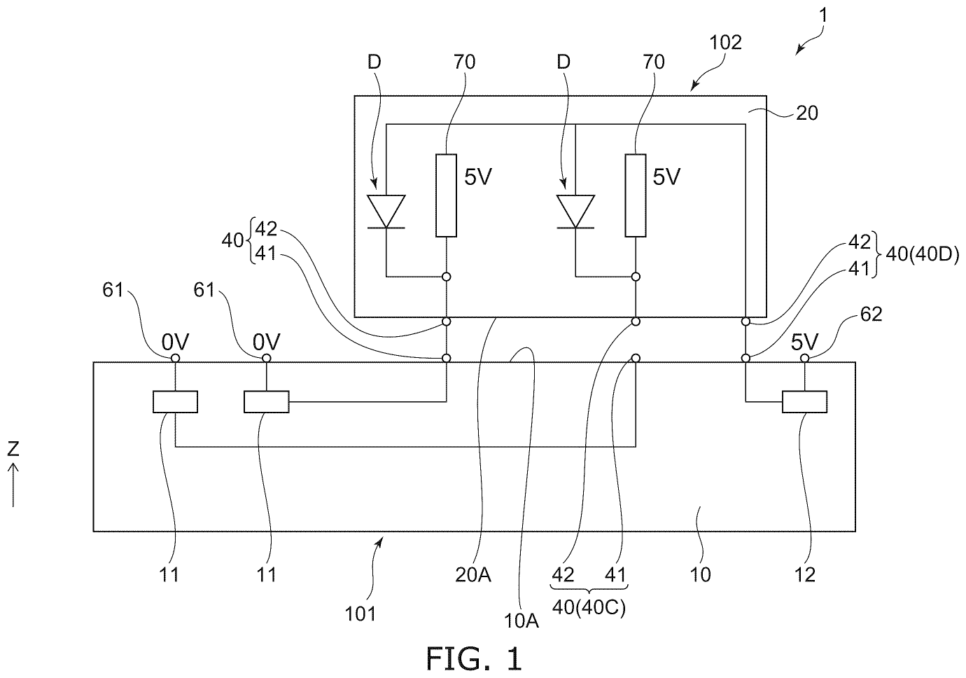

As shown in FIG. 1, an electronic device 1 of a first embodiment includes a first chip 101, a second chip 102, and multiple bonding parts 40. The multiple bonding parts 40 are located between the first chip 101 and the second chip 102. The first chip 101 and the second chip 102 are bonded to each other via the multiple bonding parts 40, and are stacked in a first direction Z.

The first chip 101 includes a first substrate 10. The first substrate 10 includes a first surface 10A. The first substrate 10 also includes a control circuit 11 and a voltage write circuit 12, which include semiconductor transistors formed at the first surface 10A side. The control circuit 11 and the voltage write circuit 12 use the semiconductor transistors to perform switching functions. The voltage write circuit 12 may be located outside the first chip 101. The first substrate 10 is, for example, a silicon substrate.

The second chip 102 includes a second substrate 20 and an electrode 70. The second substrate 20 includes a second surface 20A facing the first surface 10A of the first substrate 10 in the first direction Z. The second substrate 20 is, for example, a silicon substrate.

The multiple bonding parts 40 bond the first chip 101 and the second chip 102 and are electrically connected with the control circuit 11, the voltage write circuit 12, and the electrode 70.

The bonding parts 40 include first metal parts 41 and second metal parts 42. The first metal parts 41 are located on the first surface 10A and electrically connected with the control circuit 11 and the voltage write circuit 12. The second metal parts 42 are located on the second surface 20A and electrically connected with the electrodes 70. The first metal part 41 and the second metal part 42 face each other in the first direction Z and are bonded to each other. The bond between the first metal part 41 and the second metal part 42 is, for example, a gold-gold bond.

A first external connection part 61 and a second external connection part 62 are located on the first surface 10A of the first substrate 10. The first external connection part 61 and the second external connection part 62 are located on the first surface 10A in regions that do not face the second surface 20A of the second substrate 20. The first external connection part 61 is electrically connected with the control circuit 11. The second external connection part 62 is electrically connected with the voltage write circuit 12. The first external connection part 61 and the second external connection part 62 can be formed of the same material as the first metal part 41 by the same process as the first metal part 41.

The second substrate 20 further includes a diode D. The diode D includes a p-n junction of a first semiconductor layer of a first conductivity type and a second semiconductor layer of a second conductivity type located in the second substrate 20. In the specification, for example, the first conductivity type is taken to be a p-type; and the second conductivity type is taken to be an n-type. Or, the first conductivity type may be the n-type; and the second conductivity type may be the p-type.

The diode D is electrically connected with the electrode 70 and the bonding parts 40. The anode of the diode D is electrically connected with a bonding part 40D among the multiple bonding parts 40 that is electrically connected with the voltage write circuit 12. The bonding part 40D that is electrically connected with the voltage write circuit 12 is provided separately from the bonding part 40 electrically connected with the control circuit 11 and the electrode 70. The cathode of the diode D is electrically connected with the electrode 70 and the second metal part 42. The direction from the diode D toward the electrode 70 is the forward direction; and the direction from the control circuit 11 toward the diode D via the bonding part 40 is the reverse direction. The direction from the voltage write circuit 12 toward the diode D via the bonding part 40D is the forward direction.

### Normal Operation of Electronic Device

In a normal operation of the electronic device 1, a positive operating voltage (e.g., 5 V) or 0 V is applied to the first external connection part 61. The voltage that is applied to the first external connection part 61 is applied to the electrode 70 via the control circuit 11 and the bonding part 40. In other words, the voltage of the electrode 70 of the second chip 102 can be controlled by the first chip 101.

The electronic device 1 includes multiple first external connection parts 61, multiple control circuits 11, multiple bonding parts 40, multiple electrodes 70, and multiple diodes D, and includes multiple systems in which the individual first external connection part 61, control circuit 11, bonding part 40, electrode 70, and diode D are electrically connected to each other in each system. At least one second external connection part 62, at least one voltage write circuit 12, and at least one bonding part 40D may be included. Multiple bonding parts 40D may be included. The second external connection part 62, the voltage write circuit 12, and the bonding part 40D are electrically connected to the anodes of the multiple diodes D.

When a bonding part 40C that has a bonding defect between the first metal part 41 and the second metal part 42 is present among the multiple bonding parts 40, an electrode 70 is present that cannot be controlled to have the voltage applied to the first external connection part 61. According to the embodiment, even when the bonding part 40C that has the bonding defect is present, it is possible to adapt as described below.

### Voltage Write Operation

A voltage write operation that is described below is performed before the normal operation of the electronic device 1. First, as shown in FIG. 1, the same positive writing voltage (e.g., 5 V) as the operating voltage described above is applied to the second external connection part 62. The writing voltage is applied to the electrodes 70 via the voltage write circuit 12, the bonding part 40D, and the diodes D. The writing voltage is applied collectively to the multiple electrodes 70 via the multiple diodes D. The potentials of the multiple electrodes 70 are collectively written to be the desired potential (e.g., 5 V).

A monitor circuit that is located outside the electronic device 1 is connected to the first external connection part 61. 0 V is applied to the first external connection part 61 via the monitor circuit in the state in which the writing voltage described above is applied to the electrode 70; and the monitor circuit detects the current flowing through the control circuit 11. The bonding goodness of the bonding part 40 can be determined based on the detection result.

The current from the second external connection part 62 flows through the control circuit 11 via the diode D and the bonding part 40 that has a good bond. When the bonding part 40C that has a bonding defect is present, the current from the second external connection part 62 is blocked by the bonding part 40C having the bonding defect and does not flow through the control circuit 11. Based on the presence or magnitude of the current flowing through the control circuit 11, the bonding part 40C that has the bonding defect, i.e., the electrode 70 of which the voltage cannot be controlled by the control circuit 11, can be identified.

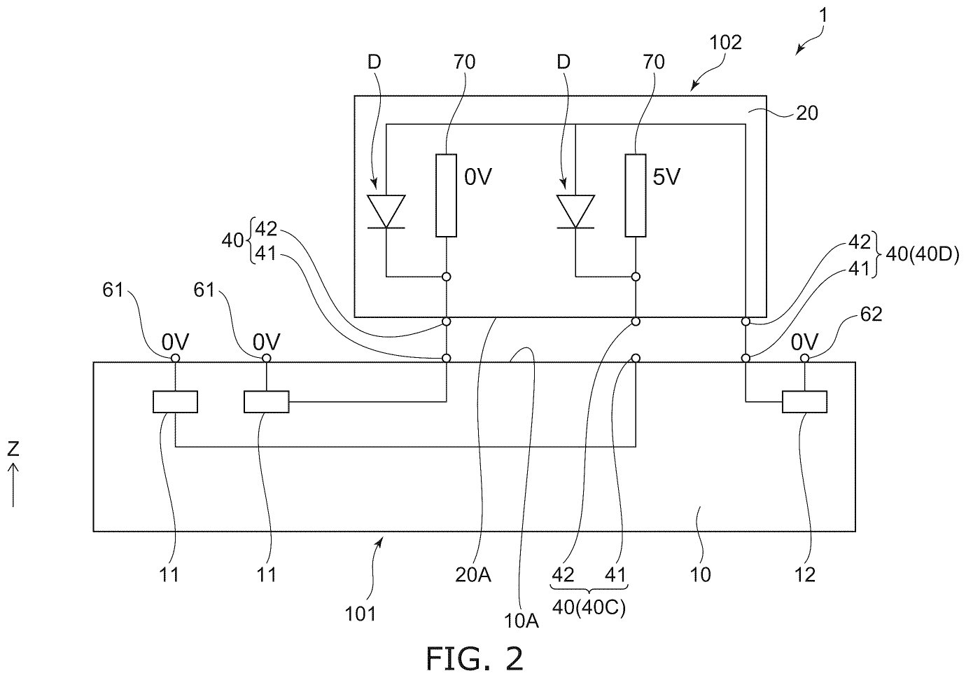

After applying the writing voltage from the second external connection part 62 to the electrodes 70 via the voltage write circuit 12 and the diodes D, 0 V is applied to the second external connection part 62 while maintaining the state in which 0 V is applied to the first external connection parts 61 as shown in FIG. 2. As a result, the potentials of the electrodes 70 connected to the bonding parts 40 having good bonds become 0 V via the bonding parts 40, the control circuits 11, the first external connection parts 61, and the monitor circuit. The potential of the electrode 70 connected to the bonding part 40C having the bonding defect becomes a floating potential; and the writing voltage described above is maintained.

In the normal operation after the write operation described above, the voltages of the electrodes 70 connected to the bonding parts 40 having good bonds can be controlled to be the operating voltage (e.g., 5 V) or 0 V according to the voltages applied to the first external connection parts 61. In the normal operation, the voltage of the electrode 70 connected to the bonding part 40C having the bonding defect is maintained at the voltage written in the write operation regardless of the voltage applied to the first external connection part 61. The writing voltage is equal to the operating voltage in the normal operation, and so in the normal operation, the voltage of the electrode 70 connected to the bonding part 40C having the bonding defect is maintained at the operating voltage (e.g., 5 V) regardless of the voltage applied to the first external connection part 61. As a result, in the normal operation, the operation is not lost even for the electrode 70 connected to the bonding part 40C having the bonding defect.

For example, the technology of the embodiment also is applicable to a sensor element of a circuit reading data in which a switch is switched on when a voltage is applied, etc. In such an element, it is favorable for the switch to remain on so that the data can be accessed.

### Second Embodiment

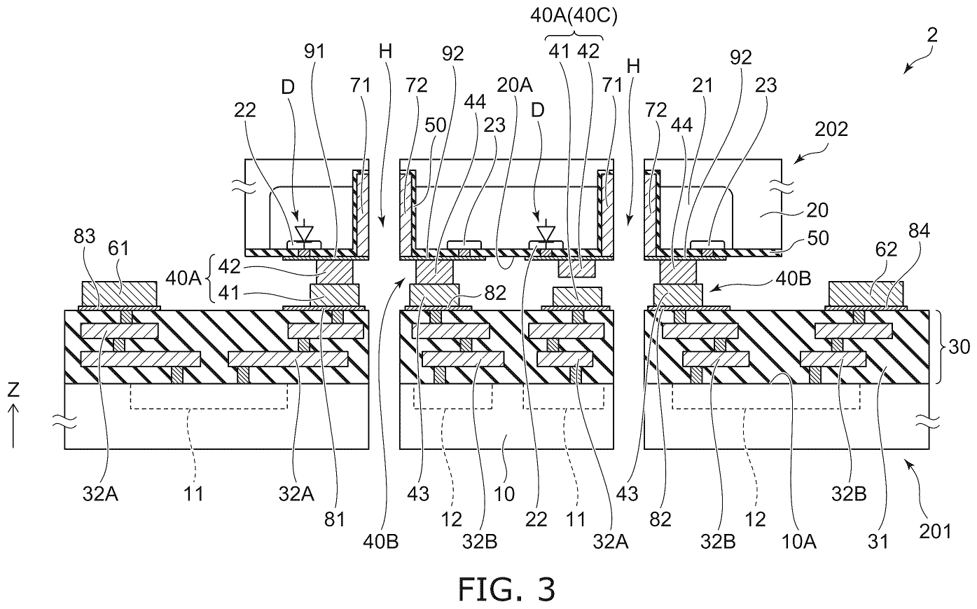

As shown in FIG. 3, an electronic device 2 of a second embodiment includes a first chip 201, a second chip 202, and the multiple bonding parts 40. The multiple bonding parts 40 are located between the first chip 201 and the second chip 202. The first chip 201 and the second chip 202 are bonded to each other via the multiple bonding parts 40, and are stacked in the first direction Z.

The first chip 201 includes the first substrate 10. The first substrate 10 includes the first surface 10A. The first substrate 10 also includes the control circuit 11 and the voltage write circuit 12 that include semiconductor transistors formed at the first surface 10A side. The control circuit 11 and the voltage write circuit 12 use the semiconductor transistors to perform switching functions. The voltage write circuit 12 may be located outside the first chip 201. The first substrate 10 is, for example, a silicon substrate.

The first chip 201 further includes a wiring part 30 located at the first surface 10A. The wiring part 30 includes an insulating layer 31, and a wiring layer located inside the insulating layer 31. The wiring layer includes a first wiring layer 32A and a second wiring layer 32B. For example, the wiring part 30 has a multilayer wiring structure in which wiring layers of different layers are electrically connected to each other by conductive vias.

The second chip 202 includes the second substrate 20, a first electrode 71, and a second electrode 72. The second substrate 20 includes a second surface 20A facing the wiring part 30 in the first direction Z. The second substrate 20 is, for example, a silicon substrate. The wiring part 30 is positioned between the first surface 10A and the second surface 20A in the first direction Z.

Multiple through-holes H extend through the second chip 202, the wiring part 30, and the first chip 201 in the first direction Z. For example, a ground potential is applied to the first and second substrates 10 and 20.

A first conductive film 91 and a second conductive film 92 are located at the second surface 20A of the second substrate 20 with an insulating film 50 interposed. The first electrode 71 and the second electrode 72 are located, with the insulating film 50 interposed, at the inner side surface of the portion of the through-hole H extending through the second substrate 20. The insulating film 50 is, for example, a silicon oxide film. The insulating film 50 is located between the second surface 20A and the first conductive film 91, between the second surface 20A and the second conductive film 92, between the first electrode 71 and the inner side surface of the through-hole H, and between the second electrode 72 and the inner side surface of the through-hole H.

The first electrode 71 and the second electrode 72 are separated from each other in the circumferential direction of the inner side surface at the inner side surface of the through-hole H. The first conductive film 91 and the second conductive film 92 are separated from each other on the insulating film 50. The first electrode 71 is electrically connected with the first conductive film 91. The second electrode 72 is electrically connected with the second conductive film 92. In the normal operation, mutually-different potentials are applied to the first and second electrodes 71 and 72.

A third conductive film 81, a fourth conductive film 82, a fifth conductive film 83, and a sixth conductive film 84 are arranged to be separated from each other on the wiring part 30. The third conductive film 81 and the fifth conductive film 83 are electrically connected with the control circuit 11 via the first wiring layer 32A and conductive vias of the wiring part 30. The fourth conductive film 82 and the sixth conductive film 84 are electrically connected with the voltage write circuit 12 via the second wiring layer 32B and conductive vias of the wiring part 30.

The multiple bonding parts 40 electrically connect the first chip 201 and the second chip 202 and bond the first chip 201 and the second chip 202. Each bonding part 40 includes metal parts that are located respectively at the first chip 201 side and the second chip 202 side and are bonded to each other. The multiple bonding parts 40 include a first bonding part 40A and a second bonding part 40B. Multiple first bonding parts 40A and multiple second bonding parts 40B are located between the wiring part 30 and the second surface 20A of the second chip 202.

The first bonding part 40A includes the first metal part 41 and the second metal part 42. The first metal part 41 contacts the third conductive film 81 and is electrically connected with the control circuit 11 via the third conductive film 81, conductive vias, and the first wiring layer 32A. The second metal part 42 contacts the first conductive film 91 and is electrically connected with the first electrode 71 via the first conductive film 91. The first metal part 41 and the second metal part 42 face each other in the first direction Z and are bonded to each other.

The second bonding part 40B includes a third metal part 43 and a fourth metal part 44. The third metal part 43 contacts the fourth conductive film 82 and is electrically connected with the voltage write circuit 12 via the fourth conductive film 82, conductive vias, and the second wiring layer 32B. The fourth metal part 44 contacts the second conductive film 92 and is electrically connected with the second electrode 72 via the second conductive film 92. The third metal part 43 and the fourth metal part 44 face each other in the first direction Z and are bonded to each other.

The first external connection part 61 and the second external connection part 62 are located on the wiring part 30. The first external connection part 61 and the second external connection part 62 are located on the wiring part 30 in regions that do not face the second surface 20A of the second substrate 20. The first external connection part 61 contacts the fifth conductive film 83 and is electrically connected with the control circuit 11 via the fifth conductive film 83, conductive vias, and the first wiring layer 32A. The second external connection part 62 contacts the sixth conductive film 84 and is electrically connected with the voltage write circuit 12 via the sixth conductive film 84, conductive vias, and the second wiring layer 32B. The first external connection part 61 and the second external connection part 62 can be formed of the same material as the first and third metal parts 41 and 43 in the same process as the first and third metal parts 41 and 43.

The second substrate 20 further includes the diode D. Multiple diodes D are arranged in the second substrate 20 to correspond to the multiple first electrodes 71. The diode D includes a p-type first semiconductor layer 21 (a p-type well) located in the second substrate 20, and an n-type second semiconductor layer 22 located inside the first semiconductor layer 21. The first semiconductor layer 21 and the second semiconductor layer 22 have a p-n junction. The first semiconductor layer 21 functions as the anode of the diode D; and the second semiconductor layer 22 functions as the cathode of the diode D.

The second semiconductor layer 22 is electrically connected with the first conductive film 91 by a conductive via extending through the insulating film 50 located on the second surface 20A. Accordingly, the cathode of the diode D is electrically connected with the first bonding part 40A via the first conductive film 91.

The second substrate 20 can include a p-type third semiconductor layer 23 that is located inside the first semiconductor layer 21 and has a higher p-type impurity concentration than the first semiconductor layer 21. The third semiconductor layer 23 functions as a contact layer of the diode D at the anode side. The third semiconductor layer 23 is electrically connected with the second conductive film 92 by a conductive via extending through the insulating film 50 located on the second surface 20A. Accordingly, the anode of the diode D is electrically connected with the second bonding part 40B via the second conductive film 92.

The anode of the diode D (the first semiconductor layer 21) is electrically connected with the second external connection part 62 via the second bonding part 40B, the second wiring layer 32B, and the voltage write circuit 12. The cathode of the diode D (the second semiconductor layer 22) is electrically connected with the first electrode 71 and the first bonding part 40A. The direction from the diode D toward the first electrode 71 via the first conductive film 91 is the forward direction. The direction from the control circuit 11 toward the diode D via the first bonding part 40A is the reverse direction. The direction from the voltage write circuit 12 toward the diode D via the second bonding part 40B is the forward direction.

The electronic device 2 of the second embodiment can be used as a pixel array that deflects electron beams of a multi-electron beam lithography apparatus that uses multiple electron beams to draw a pattern in a resist on a substrate of glass, etc. The electron beam passes through the through-hole H. The electron beam that passes through the through-hole H can be deflected by the electric field generated between the first electrode 71 and the second electrode 72.

By bonding two chips (the first chip 201 and the second chip 202) that each have through-holes, the electronic device 2 that has a deep through-hole that would be difficult to form in a solitary chip can be configured.

Normal operation of electronic device In the normal operation of the electronic device 2, a positive operating voltage (e.g., 5 V) or 0 V is applied to the first external connection part 61. The voltage that is applied to the first external connection part 61 is applied to the first electrode 71 via the first wiring layer 32A, the control circuit 11, the first bonding part 40A, and the first conductive film 91.

0 V is applied to the second external connection part 62. 0 V that is applied to the second external connection part 62 is applied to the second electrode 72 via the second wiring layer 32B, the voltage write circuit 12, the second bonding part 40B, and the second conductive film 92.

When 0 V is applied to the first and second electrodes 71 and 72, the electron beam that passes through the through-hole H is not deflected, and is irradiated on the drawing object. When 0 V is applied to the second electrode 72 and the operating voltage (e.g., 5 V) is applied to the first electrode 71, the electron beam that passes through the through-hole H is deflected, and is not irradiated on the drawing object.

When the bonding part 40C that has a bonding defect between the first metal part 41 and the second metal part 42 is present among the multiple first bonding parts 40A, the operating voltage cannot be applied to the first electrode 71 that is to be connected with the bonding part 40C having the bonding defect; and the electron beam that passes through the through-hole H cannot be deflected. This results in a defect in which the electron beam is undesirably irradiated at a position at which drawing is not to be performed. According to the embodiment, even when the bonding part 40C having the bonding defect is present, it is possible to adapt as described below.

### Voltage Write Operation

The voltage write operation described below is performed before the electronic device 2 performs the normal operation (the drawing operation of the electron beam on the drawing object). First, the same positive writing voltage (e.g., 5 V) as the operating voltage described above is applied to the second external connection part 62. The writing voltage is applied to the first electrodes 71 via the voltage write circuit 12, the second wiring layer 32B, the second bonding part 40B, the second conductive film 92, the diodes D, and the first conductive films 91. The writing voltage is collectively applied to the multiple first electrodes 71 via the multiple diodes D. The potentials of the multiple first electrodes 71 are collectively written to the desired potential (e.g., 5 V).

A monitor circuit that is located outside the electronic device 2 is connected to the first external connection part 61. 0 V is applied to the first external connection part 61 via the monitor circuit in the state in which the writing voltage described above is applied to the first electrode 71; and the current that flows through the control circuit 11 is detected by the monitor circuit. The bonding goodness of the first bonding part 40A can be determined based on the detection result.

The current from the second external connection part 62 flows through the control circuits 11 via the diodes D, the first conductive films 91, and the first bonding parts 40A having good bonds. When the bonding part 40C that has a bonding defect is present, the current from the second external connection part 62 is blocked by the bonding part 40C having the bonding defect, and does not flow through the control circuit 11. The bonding part 40C that has the bonding defect, i.e., the first electrode 71 of which the voltage cannot be controlled by the control circuit 11, can be identified based on the presence or magnitude of the current flowing through the control circuit 11.

After applying the writing voltage from the second external connection part 62 to the first electrodes 71 via the voltage write circuit 12, the second bonding part 40B, and the diodes D, 0 V is applied to the second external connection part 62 while maintaining a state in which 0 V is applied to the first external connection parts 61. As a result, the potentials of the first electrodes 71 connected to the first bonding parts 40A having good bonds are set to 0 V via the first conductive films 91, the first bonding parts 40A, the first wiring layer 32A, the control circuits 11, the first external connection parts 61, and the monitor circuit. The potential of the first electrode 71 connected to the bonding part 40C having the bonding defect becomes a floating potential; and the writing voltage described above is maintained.

In the normal operation after the write operation described above, the voltage of the first electrode 71 connected to the first bonding part 40A having the good bond can be controlled to be the operating voltage (e.g., 5 V) or 0 V according to the voltage applied to the first external connection part 61. In the normal operation, the voltage of the first electrode 71 connected to the bonding part 40C having the bonding defect is maintained at the voltage written in the write operation, regardless of the voltage applied to the first external connection part 61. The writing voltage is equal to the operating voltage in the normal operation, and so in the normal operation, the voltage of the first electrode 71 connected to the bonding part 40C having the bonding defect is maintained at the operating voltage (e.g., 5 V) regardless of the voltage applied to the first external connection part 61. As a result, even when the bonding part 40C that has a bonding defect is present, the electron beam that passes through the through-hole H at which the first electrode 71 connected to the bonding part 40C having the bonding defect is located can be deflected, and a defect of the electron beam being undesirably irradiated on a position at which drawing is not to be performed can be avoided.

In the normal operation, the first electrode 71 that is connected to the bonding part 40C having the bonding defect can no longer be controlled to be 0 V. Therefore, the electron beam that passes through the through-hole H (the defective pixel) at which the first electrode 71 connected to the bonding part 40C having the bonding defect is located can no longer be irradiated on the drawing object.

Although it is desirable to avoid defects in which the electron beam is undesirably irradiated at a position at which drawing is not to be performed, there are cases where a prescribed number of defects in which the electron beam is not irradiated at the position to be drawn are allowed. The latter defect can be remedied using other normal pixels positioned around the defective pixel that includes the first electrode 71 connected to the bonding part 40C having the bonding defect.

For example, in a technique in which one pixel is formed by irradiating an electron beam multiple times, the electron beam is irradiated, the mask is then moved slightly, then the irradiation of the electron beam is repeated, and the defective pixel can be remedied by using multiple electron beams to form one pixel.

If the voltage of the first electrode 71 connected to the bonding part 40C having the bonding defect drops due to current leakage, etc., the voltage of the first electrode 71 connected to the bonding part 40C having the bonding defect can be maintained at the operating voltage by performing the write operation described above again. For example, the drop of the voltage of the first electrode 71 connected to the bonding part 40C having the bonding defect can be detected by monitoring the deflection amount of the electron beam.

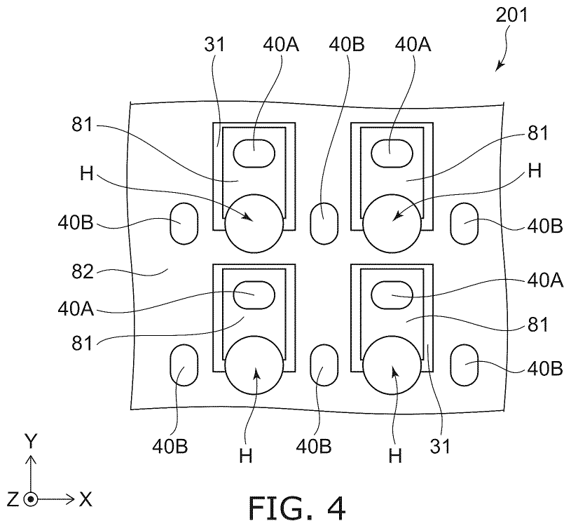

FIG. 4 is a schematic plan view showing an example of a configuration of the electronic device 2 at the first surface 10A side of the first substrate 10. In FIG. 4, a second direction X and a third direction Y are orthogonal to each other in a plane parallel to the first surface 10A. The second direction X and the third direction Y also are orthogonal to the first direction Z.

The multiple through-holes H are arranged in the second and third directions X and Y. The third conductive films 81 are arranged with a one-to-one correspondence to the through-holes H. The first bonding parts 40A are arranged in contact with the third conductive films 81 with a one-to-one correspondence with the through-holes H. One through-hole H is positioned between the first bonding parts 40A adjacent to each other in the third direction Y. One through-hole H is positioned between the second bonding parts 40B adjacent to each other in the second direction X. Two second bonding parts 40B are provided for one through-hole H and arranged with the through-hole H interposed in the second direction X. The number of the second bonding parts 40B is greater than the number of the first bonding parts 40A. The potentials of the multiple second electrodes 72 can be collectively controlled via the multiple second bonding parts 40B and the common fourth conductive film 82. The potentials of the multiple first electrodes 71 are individually controlled via the corresponding first bonding part 40A and the corresponding third conductive film 81.

The multiple second bonding parts 40B are located on the common fourth conductive film 82 and contact the fourth conductive film 82. As shown in FIG. 3, the multiple second bonding parts 40B have a common connection with the first semiconductor layers 21 that are the anodes of the diodes D. Accordingly, even when the second bonding part 40B that has a bonding defect is present among the multiple second bonding parts 40B, the writing voltage can be collectively applied to the multiple first electrodes 71 via the diodes D in the write operation described above via the other second bonding parts 40B having good bonds.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

What is claimed is:

1. An electronic device, comprising:
a first chip including a first substrate, the first substrate including a first surface and a control circuit;
a second chip including a second substrate and an electrode, the second substrate including a second surface facing the first surface in a first direction; and
a plurality of bonding parts located between the first surface and the second surface, one of the plurality of bonding parts electrically connecting the control circuit and the electrode, the plurality of bonding parts bonding the first chip and the second chip,
the second substrate including a diode electrically connected with the electrode and the plurality of bonding parts,
a direction from the diode toward the electrode being a forward direction of the diode,
a direction from the control circuit toward the diode via the one of the plurality of bonding parts being a reverse direction of the diode.

2. The electronic device according to claim 1, wherein
the diode includes:
a first semiconductor layer located in the second substrate, the first semiconductor layer being of a first conductivity type; and
a second semiconductor layer located inside the first semiconductor layer, the second semiconductor layer being of a second conductivity type.

3. The electronic device according to claim 2, wherein
the second chip includes a conductive film located on the second surface, and
the conductive film is electrically connected with the second semiconductor layer, the electrode, and the one of the plurality of bonding parts.

4. The electronic device according to claim 1, further comprising:
a through-hole extending through the second and first substrates in the first direction,
the electrode being a first electrode,
the second chip including a second electrode,
the first electrode and the second electrode being located at an inner side surface of a portion of the through-hole extending through the second substrate,
the plurality of bonding parts including
a first bonding part electrically connected with the control circuit, the first electrode, and a cathode of the diode, and
a second bonding part electrically connected with the second electrode and an anode of the diode.

5. The electronic device according to claim 4, wherein
the first electrode and the second electrode are separated from each other in a circumferential direction of the inner side surface at the inner side surface of the through-hole.

6. The electronic device according to claim 1, wherein
the first chip includes a wiring part located between the first surface and the second surface, and
the wiring part includes a wiring layer electrically connected with the control circuit and the one of the plurality of bonding parts.

7. The electronic device according to claim 4, wherein
the first chip includes a wiring part located between the first surface and the second surface, and
the wiring part includes a wiring layer electrically connected with the control circuit and the first bonding part.

8. The electronic device according to claim 7, wherein
the wiring layer is a first wiring layer,
the wiring part further includes a second wiring layer,
the first wiring layer is electrically connected with the first electrode, and
the second wiring layer is electrically connected with the second electrode.

9. The electronic device according to claim 1, wherein
the first chip further includes an external connection part located on the first surface of the first substrate in a region not facing the second surface of the second substrate, and
the external connection part is electrically connected with the control circuit.

10. The electronic device according to claim 1, wherein
the first substrate is a silicon substrate, and
the control circuit includes a semiconductor transistor.

11. A method for operating the electronic device according to claim 1, the method comprising:
applying a voltage from a voltage write circuit to the electrode via the diode; and
applying 0 V to the plurality of bonding parts after the applying of the voltage to the electrode.

12. The method according to claim 11, further comprising:
determining a bonding goodness of at least one of the plurality of bonding parts based on a current flowing through the control circuit in a state in which the voltage is applied to the electrode.

13. The method according to claim 11, wherein
the electronic device further includes a through-hole extending through the second and first substrates in the first direction,
the electrode is a first electrode,
the second chip includes a second electrode,
the first electrode and the second electrode are located at an inner side surface of a portion of the through-hole extending through the second substrate,
the plurality of bonding parts includes:
a first bonding part electrically connected with the control circuit, the first electrode, and a cathode of the diode; and
a second bonding part electrically connected with the second electrode and an anode of the diode, and
the method further comprises:
applying the voltage to the first electrode via the second bonding part and the diode.

14. The method according to claim 13, wherein
mutually-different potentials are applied to the first and second electrodes.
